(19) United States
(12) Patent Application Publication
(10) Pub. No.: US 2024/0420952 A1
(43) Pub. Date: Dec. 19, 2024

(54) NESTED-LOOP PLASMA ENHANCED ATOMIC LAYER DEPOSITION

(71) Applicant: Applied Materials, Inc., Santa Clara, CA (US)

(72) Inventors: Bhaskar Soman, San Jose, CA (US); Supriya Ghosh, San Jose, CA (US); Yanze Wu, Sunnyvale, CA (US); Zeqing Shen, San Jose, CA (US); Susmit Singha Roy, Campbell, CA (US); Abhijit Basu Mallick, Sunnyvale, CA (US)

(73) Assignee: Applied Materials, Inc., Santa Clara, CA (US)

(21) Appl. No.: 18/209,700

(22) Filed: Jun. 14, 2023

(51) Int. Cl. H01L 21/02; H01L 21/3205; H01L 21/321

(52) U.S. Cl. CPC H01L 21/0228; H01L 21/0214; H01L 21/02164; H01L 21/02211; H01L 21/02238; H01L 21/02252; H01L 21/02274; H01L 21/0234; H01L 21/32055; H01L 21/32105

(57) ABSTRACT

Exemplary methods of semiconductor processing may include iteratively repeating a deposition cycle several times on a substrate disposed within a processing region of a semiconductor processing chamber. Each deposition cycle may include depositing a silicon-containing material on the substrate and exposing the silicon-containing material to a first oxygen plasma to convert the silicon-containing material to a silicon-and-oxygen-containing material. After the iterative repeating of the deposition cycle, the method may include performing a densification operation by exposing the silicon-and-oxygen-containing material to a second oxygen plasma to produce a densified silicon-and-oxygen-containing material where the quality of the densified silicon-and-oxygen-containing material is greater than the silicon-and-oxygen-containing material. The method may further include iteratively repeating the iteratively repeated deposition cycles and the densification operation several times.

### TECHNICAL FIELD

The present technology relates to methods and components for semiconductor processing. More specifically, the present technology relates to systems and methods for depositing silicon-containing materials with decreased overall process time.

### BACKGROUND

Integrated circuits are made possible by processes which produce intricately patterned material layers on substrate surfaces. Producing patterned material on a substrate is a multistage process that includes a plurality of stages that form material on and remove material from the substrate in a controlled manner. The longer each individual stage is, the lower the product throughput. Unfortunately, while reducing the time of individual stages (or steps within an individual stage) increases throughput, the quality of the final product is often sacrificed. Thus, there is a need for improved systems and methods that can be used to produce high quality devices and structures faster to enable higher throughput.

### SUMMARY

Exemplary methods of semiconductor processing may include iteratively repeating a deposition cycle several times on a substrate disposed within a processing region of a semiconductor processing chamber. Each deposition cycle may include depositing a silicon-containing material on the substrate and exposing the silicon-containing material to a first oxygen plasma to convert the silicon-containing material to a silicon-and-oxygen-containing material. After the iterative repeating of the deposition cycle, the method may include performing a densification operation by exposing the silicon-and-oxygen-containing material to a second oxygen plasma to produce a densified silicon-and-oxygen-containing material where the quality of the densified silicon-and-oxygen-containing material is greater than the silicon-and-oxygen-containing material. The method may further include iteratively repeating the iteratively repeated deposition cycles and the densification operation several times.

Exemplary methods of semiconductor processing may include iteratively repeating a deposition cycle x times (e.g., 3≤x≤100) on a substrate disposed within a processing region of a semiconductor processing chamber, wherein 3≤x≤100. The deposition cycle may include depositing a silicon-containing material on the substrate followed by purging the processing region after operation, and then exposing the silicon-containing material to a first oxygen plasma to convert the silicon-containing material to a silicon-and-oxygen-containing material followed by purging the processing region after operation. The first oxygen plasma may be generated at a first plasma power, and the exposing may be for a first time. Optionally, the method may further include repeating the depositing followed by purging steps. Then, the method may include performing a densification operation by exposing the silicon-and-oxygen-containing material to a second oxygen plasma to produce a densified silicon-and-oxygen-containing material. The second oxygen plasma may be generated at a second plasma power, and the exposing may be for a second time. The first plasma power may be lower than the second plasma power, and/or the first time may be shorter than the second time. The method may further include iteratively repeating the iteratively repeated deposition cycles and the densification operation y times (e.g., 2≤y≤50).

In some embodiments, 5≤x≤50 and/or 3≤y≤10 may be true. In some instances, the deposition cycle may be 3 seconds or less. The first plasma power may be about 100 W to about 2500 W, and the second plasma power may be about 1500 W to about 2500 W. The first time may be about 0.1 seconds to about 1 second, and the second time may be about 1 second to about 30 seconds. In some embodiments, the substrate may define one or more features along the substrate, and wherein the silicon-and-oxygen-containing material extends within the one or more features along the substrate. A pressure within the processing region may be maintained at greater than or about 100 Torr while depositing the silicon-containing material on the substrate. The silicon-containing material may be or may be derived from a silicon-containing precursor that comprises one or more of: silane (SiH₄), dislane (Si₂H₆), silicon tetrachloride (SiCl₄), tetraethyl orthosilicate (TEOS), and aminosilane. The silicon-and-oxygen-containing material, after iteratively repeating the deposition cycle, may have a thickness of about 3 Å to about 100 Å. The silicon-and-oxygen-containing material may have a compressive stress of about −225 MPa to about −50 MPa, and the densified silicon-and-oxygen-containing material may have a compressive stress of about −350 MPa to about −200 MPa, such that the compressive stress of the silicon-and-oxygen-containing material is greater than the compressive stress of the densified silicon-and-oxygen-containing material. The silicon-and-oxygen-containing material may have a wet etch rate ratio (WERR) (in 1% HF) relative to thermal oxide of about 1.5 to about 4, and the densified silicon-and-oxygen-containing material may have a WERR (in 1% HF) relative to thermal oxide of about 0.1 to about 2, such that the WERR of the silicon-and-oxygen-containing material is greater than the WERR of the densified silicon-and-oxygen-containing material. The silicon-and-oxygen-containing material may have a refractive index of about 1 to about 1.5, and the densified silicon-and-oxygen-containing material may have a refractive index of about 1.1 to about 2, such that the refractive index of the silicon-and-oxygen-containing material is less than the refractive index of the densified silicon-and-oxygen-containing material.

Some embodiments on the present technology may encompass semiconductor processing methods. The methods may include iteratively repeating a deposition cycle x times (e.g., 3≤x≤100) on a substrate in a processing region of a semiconductor processing chamber. The deposition cycle may include depositing a silicon-containing material on the substrate followed by purging the processing region, and then exposing the silicon-containing material to a first oxygen plasma to convert the silicon-containing material to a silicon-and-oxygen-containing material followed by purging the processing region. The first oxygen plasma may be generated at a first plasma power, and the exposing may be for a first time. In each iteration of the deposition cycle, the first plasma power may be about 100 W to about 2500 W, and the first time may be about 0.2 seconds to 3 seconds, each independently chosen for each iteration of the deposition cycle. Optionally, the method may further include repeating the depositing followed by purging steps. The method may then further include performing a densification operation by exposing the silicon-and-oxygen-containing material to a second oxygen plasma to produce a densified silicon-and-oxygen-containing material. The second oxygen plasma may be generated at a second plasma power, and the exposing may be for a second time. The first plasma power may be lower than the second plasma power, and/or the first time may be shorter than the second time. In each iteration of the densification operation, the second plasma power may be about 1000 W to about 2500 W, and the second time may be about 1 second to 40 seconds, each independently chosen for each iteration of the densification operation. The method may further include iteratively performing the deposition cycle followed by the densification y times (e.g., 2≤y≤50) while the substrate is maintained in the processing region.

In some embodiments, 5≤x≤50 and/or 3≤y≤20 may be true. The deposition cycle may be 1.5 seconds or less. The first plasma power may be about 500 W to about 2500 W, and the second plasma power may be about 1500 W to about 2500 W. The first time may be about 0.1 seconds to about 0.7 seconds, and the second time may be about 3 seconds to about 25 seconds.

Some embodiments on the present technology may encompass semiconductor processing methods. The methods may include iteratively repeating a deposition cycle x times (e.g., 3≤x≤100) on a substrate in a processing region of a semiconductor processing chamber. The deposition cycle may include depositing a silicon-containing material on the substrate followed by purging the processing region, and then exposing the silicon-containing material to a first oxygen plasma to convert the silicon-containing material to a silicon-and-oxygen-containing material followed by purging the processing region. The first oxygen plasma may be generated at a first plasma power, and the exposing may be for a first time. In each iteration of the deposition cycle the first plasma power and the first time may vary. Optionally, the method may further include repeating the depositing followed by purging steps. The method may then further include performing a densification operation by exposing the silicon-and-oxygen-containing material to a second oxygen plasma to produce a densified silicon-and-oxygen-containing material. The second oxygen plasma may be generated at a second plasma power, and the exposing may be for a second time. In each iteration of the densification operation, the second plasma power and the second time may be vary. The first plasma power may be lower than the second plasma power and/or the first time may be shorter than the second time. The method may further include iteratively performing the deposition cycle followed by the densification y times (e.g., 2≤y≤50) while the substrate is maintained in the processing region. Each iteration of the iteratively performed deposition cycle followed by the densification operation a layer of the densified silicon-and-oxygen-containing material having a thickness of about 3 Å to about 100 Å.

Such technology may provide numerous benefits over conventional systems and techniques. For example, embodiments of the present technology may decrease the processing time and increase product throughput. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3F show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As demand for devices increases, increasing production throughput is desired. However, simply increasing speed by decreasing the time for individual stages of the production process often decreases the quality of the final product. The present technology seeks to increase the speed of plasma enhanced atomic layer deposition methods by using nested loops of operations. More specifically, the processing method includes a deposition cycle loop (or an iteratively repeated deposition cycle) nested within the processing method loop. An individual processing method loop includes performing a deposition cycle loop followed by a densification operation. The deposition cycle loop produces a layer of silicon-and-oxygen-containing material, then the densification operation improves the quality of the silicon-and-oxygen-containing material. The deposition cycle loop is then repeated to form another portion of silicon-and-oxygen-containing material on top of the increased quality silicon-and-oxygen-containing material. The newly deposited silicon-and-oxygen-containing material is treated again using a second densification operation to improve the quality of the newly deposited silicon-and-oxygen-containing material. This is repeated until a desired amount of silicon-and-oxygen-containing material is present on the substrate, such as to fill a feature on the substrate.

In contrast, conventional plasma enhanced atomic layer deposition method typically include a series of deposition cycles to deposit the desired amount of material where each deposition cycle produces a high quality silicon-and-oxygen-containing material. Generally, the operation within a deposition cycle that converts a silicon-containing material to a high quality silicon-and-oxygen-containing material is the longest operation in the deposition cycle.

The present technology may reduce the overall time to deposit a desired amount of the higher quality silicon-and-oxygen-containing material on the substrate because the present technology first produces an intermediate quality silicon-and-oxygen-containing material with greatly reduced cycle times and then upgrades the intermediate quality silicon-and-oxygen-containing material to a higher quality silicon-and-oxygen-containing material with a short densification operation.

The quality of a silicon-and-oxygen-containing material may be characterized by the compressive stress (where higher compressive stress indicates higher quality), wet etch rate ratio (WERR) (in 1% HF) relative to thermal oxide (where lower WERR indicates higher quality), refractive index (RI) (where higher RI indicates higher quality), shrinkage (where less shrinkage indicates higher quality), or any combination thereof.

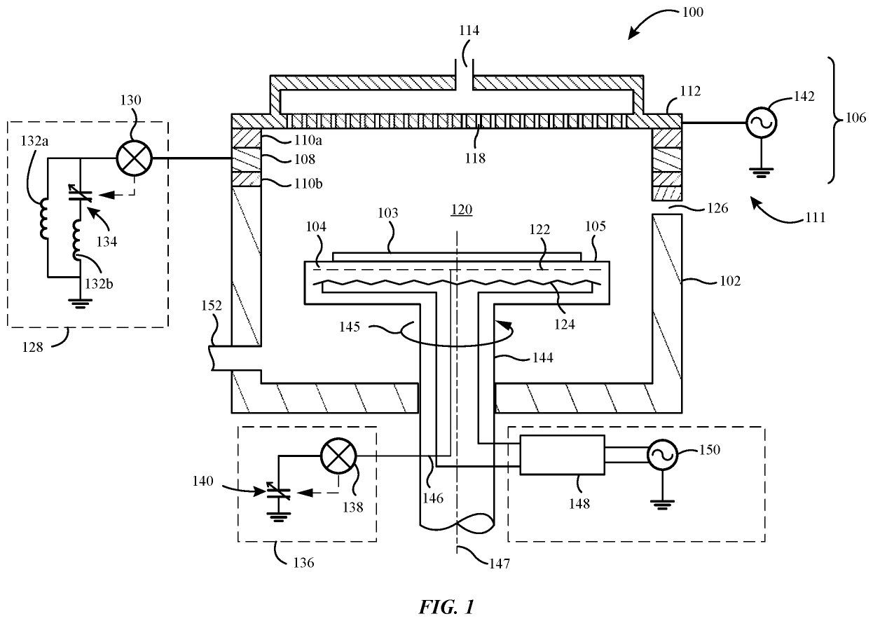

FIG. 1 shows a cross-sectional view of an exemplary semiconductor processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The semiconductor processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support 104 during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition cycle and/or a densification operation.

A plasma profile modulator 111 may be disposed in the semiconductor processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the semiconductor processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the semiconductor processing chamber 100. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the semiconductor processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132a. The second circuit leg may include a second inductor 132b coupled in series with the first electronic controller 134. The second inductor 132b may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with the surface 105 of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the semiconductor processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the semiconductor processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132a and the second inductor 132b, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support 104. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support 104 may decline. The second electronic controller 140 may have a similar effect, increasing and decreasing aerial coverage of the plasma over the substrate support 104 as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

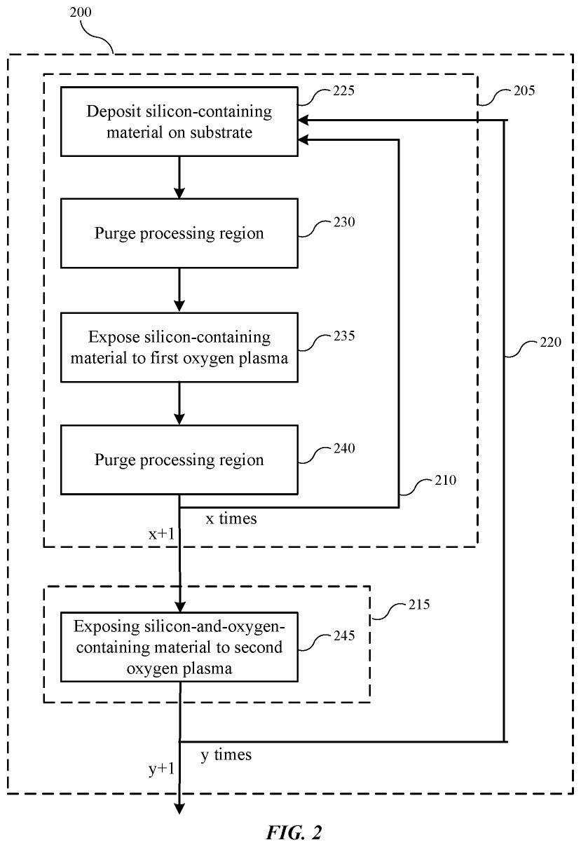

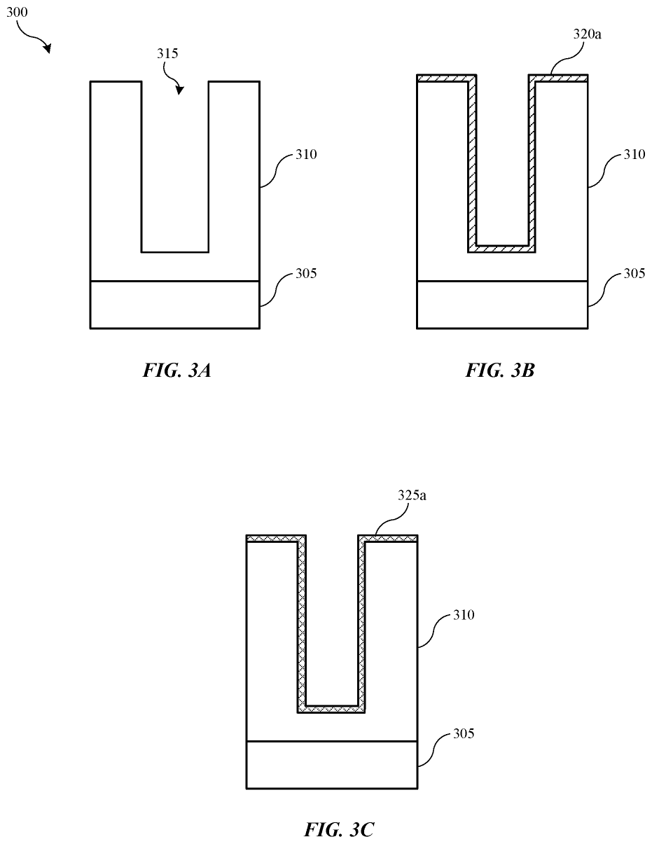

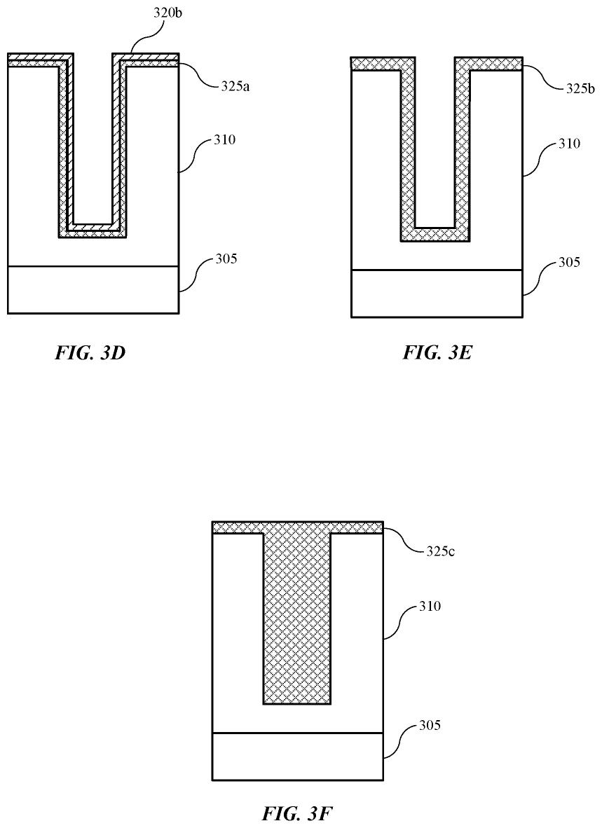

FIG. 2 shows an example of a plasma enhanced atomic layer deposition method 200 according to some embodiments of the present disclosure. The method 200 may be performed in a variety of processing chambers, including the semiconductor processing chamber 100 described below, as well as any other chambers. Method 200 may include one or more operations prior to the initiation of the method 200, including front-end processing, deposition, etching, polishing, cleaning, or any other operations that may be performed prior to the described operations. The method 200 may include a number of optional operations, which may or may not be specifically associated with some embodiments of methods according to embodiments of the present technology. For example, many of the operations are described in order to provide a broader scope of the processes performed, but are not critical to the technology, or may be performed by alternative methodology as will be discussed further below. Method 200 may describe operations shown schematically in FIGS. 3A-3F, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may or may not involve optional operations to develop the semiconductor structure to a particular fabrication operation. It is to be understood that method 200 may be performed on any number of semiconductor structures or substrates 305, as illustrated in FIG. 3A, including exemplary structure 300 on which one or more silicon-and-oxygen-containing materials may be formed. As illustrated in FIG. 2 shows operations in a semiconductor processing method according to some embodiments of the present technology.

FIGS. 3A-3F show exemplary schematic cross-sectional structures in which material layers are included and produced according to some embodiments of the present technology.

Substrate 305 may be processed to form one or more features 315, which may be recessed, such as trenches, apertures, or any other structure in semiconductor processing. Substrate 305 may be any number of materials, such as a base wafer or substrate 305 made of silicon or silicon-containing materials, other substrate materials, as well as one or more materials that may be formed overlying the substrate 305 during semiconductor processing. For example, in some embodiments the substrate 305 may be processed to include one or more materials or structures for semiconductor processing. Substrate 305 may be or include a dielectric material, such as an oxide or nitride of any number of materials. In embodiments, one or more layers of material 310 may be deposited on the substrate 305. In embodiments, the one or more layers of material 310 may be or include a silicon-containing material. The silicon-containing material may be or include silicon, including amorphous silicon, doped silicon, silicon oxide, silicon nitride, or silicon carbide.

As shown, one or more features 315 may be defined by the one or more layers of material 310 and/or substrate 305, such as a trench, aperture, or other recessed feature. The features 315 may be characterized by vertical sidewalls, as illustrated, or tapered sidewalls. In tapered sidewall embodiments, the features may be characterized by a larger diameter or width at the top of the features than at the bottom of the features. The aspect ratio of the features 315, or the ratio of the depth of the feature relative to the width or diameter of the feature at the top of the feature, may be greater than or about 1:1, and may be greater than or about 2:1, greater than or about 3:1, greater than or about 4:1, greater than or about 5:1, greater than or about 6:1, greater than or about 7:1, greater than or about 8:1, greater than or about 9:1, greater than or about 10:1, or more. Although only one feature 315 is shown in the figure, it is to be understood that exemplary structures may have any number of features 315 defined along the structure according to embodiments of the present technology.

The method 200 includes a deposition cycle 205 that iteratively repeats (or loops) 210 for x number of times followed by a densification operation 215. The method includes iteratively repeating 220 (or looping) the iteratively repeated 210 deposition cycle 205 after each densification operation 215 y number of times. Accordingly, the iteratively repeated 210 deposition cycle 205 can be characterized as a loop nested within in the overall loop that includes the iteratively repeated 210 deposition cycle 205 and the densification operation 215.

As illustrated in FIG. 3B, the iteratively repeated 210 deposition cycle 205 deposits a layer 320a comprising silicon-and-oxygen-containing material on the substrate 305 and/or one or more layers of material 310. As illustrated in FIG. 3C, the subsequent densification operation 215 coverts the layer 320a to a densified layer 325a by densifying (described in more detail below) the silicon-and-oxygen-containing material. Densifying improves the quality of the silicon-and-oxygen-containing material, such as by increasing desired mechanical properties of the material. As illustrated in FIG. 3D, the method 200 includes repeating 220 the iteratively repeated 210 deposition cycle 205 to build another layer 320b comprising the silicon-and-oxygen-containing material on the densified layer 325a. As illustrated in FIG. 3E, the layer 320b is then densified in a subsequent densification operation 215 to produce a densified layer 325b, which is of higher quality than the layer 320b. The method 200 includes repeating 220 these operations until the desired amount of densified silicon-and-oxygen-containing material is on the substrate. In embodiments, as illustrated in FIG. 3F, the method 200 may continue until the feature 315 is filled with the densified silicon-and-oxygen-containing material 325c.

The illustrated deposition cycle 205 includes four operations. The first operation 225 deposits silicon-containing material on the substrate. This may be achieved by providing a silicon-containing precursor to the processing region of the semiconductor processing chamber. The silicon-containing precursor may be provided to the same processing region of the semiconductor processing chamber to perform operations prior to the initiation of the method 200. Silicon-containing precursors that may be used in method 200 may be or include any number of silicon-containing precursors. For example, the silicon-containing precursor may be or include silane (SiH₄), dislane (Si₂H₆), silicon tetrachloride (SiCl₄), tetraethyl orthosilicate (TEOS), di-isopropyl aminosilane (DIPAS), bis (diethylamino) silane (BDEAS), bis (t-butylamino) silane (BTBAS), or any other precursor able to form, for example, a silicon oxide (SiO), a silicon nitride (SiN), or a silicon carbide (SiC) material. In some embodiments, along with the silicon-containing precursor, one or more additional precursors may be delivered, such as a hydrogen-containing precursor as well as one or more carrier or inert gases, such as argon or helium, for example.

The silicon-containing precursor deposits on the substrate as a silicon-containing material. It should be noted that “depositing on the substrate” encompasses depositing on features, layers (e.g., a layer of silicon-and-oxygen containing material or a densified layer of silicon-and-oxygen containing material), or the like that are already present on the substrate. That is, the silicon-containing material may extend along any and/or all exposed surfaces along the substrate, when exposed, as well as any other incorporated materials, such as any previously formed silicon-and-oxygen containing material or densified silicon-and-oxygen containing material. During operation 225, deposition of the silicon-containing material may occur inward within features, if present, for example, from the sidewalls defining the feature.

Depositing the silicon-containing material on the substrate at operation 225 may be performed as a plasma-free operation. By performing operation 225 plasma-free, the deposition of the silicon-containing material may be highly conformal. In embodiments, the deposition of the silicon-containing material may be characterized by a conformality of greater than or about 80%, greater than or about 85%, greater than or about 90%, greater than or about 95%, greater than or about 97%, greater than or about 99%, or about 100%.

Operation 225 may be performed for about 5 seconds or less, about 4 seconds or less, about 3 second or less, about 2 seconds or less, about 1 second or less, about 0.5 seconds or less, about 0.1 seconds to about 5 seconds, about 0.1 seconds to about 0.5 seconds, about 0.25 seconds to about 1 second, about 0.25 seconds to about 1.5 seconds, about 1 second to about 3 seconds, or about 2 seconds to about 5 seconds. Without being limited by theory it is believed that shorter times reduces the amount (or thickness) of silicon-containing material deposited on the surface. Further, it is believed that if insufficient amounts of the silicon-containing material (e.g., because of lower times for operation 225) produces a lower quality silicon-and-oxygen-containing material at the end of each of the deposition cycles 205. However, because a single layer is deposited in operation 225 longer times may reach a self-limiting saturation.

After operation 225, operation 230 may be performed where the processing region is purged to remove excess silicon-containing precursor. Purging may be achieved by reducing the pressure in the semiconductor processing chamber or flowing a gas (e.g., an inert gas like argon or nitrogen) through the semiconductor processing chamber.

Without being limited by theory, it is believed that lower purge times do not remove a sufficient amount of the excess silicon-containing precursor, which may make the following operation 135 less effective and reduce the quality of the silicon-and-oxygen-containing material at the end of each of the deposition cycles 205.

Operation 230 may be performed for about 5 seconds or less, about 4 seconds or less, about 3 second or less, about 2 seconds or less, about 1 second or less, about 0.5 seconds or less, about 0.1 seconds to about 5 seconds, about 0.1 seconds to about 0.5 seconds, about 0.25 seconds to about 1 second, about 0.25 seconds to about 1.5 seconds, about 1 second to about 3 seconds, or about 2 seconds to about 5 seconds.

After operation 230, the method 200 may include operation 235 that exposes the silicon-containing material to an oxygen plasma to convert the silicon-containing material to a silicon-and-oxygen-containing material. The plasma may be formed from an oxygen-containing precursor. Oxygen-containing precursors that may be used in method 200 may be or include any number of oxygen-containing precursors. For example, the oxygen-containing precursor may be or include nitrous oxide (N₂O), water (H₂O), diatomic oxygen (O₂), ozone (O₃), a combination of one or more of these, or any other oxygen-containing materials. Inert gas like argon may also be present.

The quality of the resultant silicon-and-oxygen-containing material depends on, among other things, the plasma power and the exposure time. Without being limited by theory, it is believed that higher plasma power and/or higher exposure times increase the quality of the silicon-and-oxygen-containing material at the end of each of the deposition cycles 205 because the resultant silicon-and-oxygen-containing material has a higher density. However, longer exposure times increase the length of time for each of the deposition cycles 205 and the overall method 200. Further, if the plasma power and/or the exposure time are too low, the conversion of the silicon-containing material to the silicon-and-oxygen-containing material may be incomplete, which reduces the quality of the silicon-and-oxygen-containing material. Therefore, in the present disclosure, a balance between the plasma power and the exposure time is desired to achieve a silicon-and-oxygen-containing material with intermediate quality that can then be upgraded to the higher quality silicon-and-oxygen-containing material in the densification operation 215.

The plasma power in operation 235 may be about 2500 Watts (W) or less, about 2000 W or less, about 1750 W or less, about 1500 W or less, about 1250 W or less, about 1000 W or less, about 1 W to about 2500 W, about 1 W to about 500 W, about 100 W to about 2500 W, about 100 W to about 1000 W, about 500 W to about 2500 W, or about 1000 W to about 2500 W.

The exposure time (or length of time of operation 235 is performed) may be about 5 seconds or less, about 4 seconds or less, about 3 second or less, about 2 seconds or less, about 1 second or less, about 0.5 seconds or less, about 0.1 seconds to about 5 seconds, about 0.1 seconds to about 0.5 seconds, about 0.25 seconds to about 1 second, about 0.25 seconds to about 1.5 seconds, about 1 second to about 3 seconds, or about 2 seconds to about 5 seconds.

While forming the plasma of the oxygen-containing precursor, a temperature within the semiconductor processing chamber may be maintained at greater than or about 450° C., and may be maintained at greater than or about 500° C., greater than or about 550° C., greater than or about 600° C., or more. The temperature may be maintained at less than or about 650° C. while forming the plasma of the oxygen-containing precursor, and may be maintained at less than or about 600° C., less than or about 550° C., less than or about 500° C., or less. In embodiments where the plasma of the oxygen-containing precursor is formed, the oxygen-containing precursor may include a one or both of N₂O and O₂.

After operation 235, operation 240 may be performed where the processing region is purged to remove remnants from the oxygen plasma and byproducts from the conversion of the silicon-containing material to the silicon-and-oxygen-containing material. Purging may be achieved by reducing the pressure in the semiconductor processing chamber or flowing a gas (e.g., an inert gas like argon or nitrogen) through the semiconductor processing chamber.

Operation 240 may be performed for about 5 seconds or less, about 4 seconds or less, about 3 second or less, about 2 seconds or less, about 1 second or less, about 0.5 seconds or less, about 0.1 seconds to about 5 seconds, about 0.1 seconds to about 0.5 seconds, about 0.25 seconds to about 1 second, about 0.25 seconds to about 1.5 seconds, about 1 second to about 3 seconds, or about 2 seconds to about 5 seconds. Without being limited by theory, it is believed that the length of time for the operation 240 has minimal impact on the quality of the resultant silicon-and-oxygen-containing material but does impact the overall time for each of the deposition cycles 210. Therefore, operation 240 may be preferably minimized.

While the illustrated deposition cycle 205 illustrates four operations 225, 230, 235, 240, the deposition cycle may include other operations or not include one or more of the illustrated operations 225, 230, 235, 240.

The conditions for each operation within the deposition cycle 205 may be chosen to achieve a silicon-and-oxygen-containing material with the properties described above. Preferably, the conditions other than time are selected to allow for each operation to be a minimal time while achieving the desired properties (e.g., intermediate quality, which can be characterized by compressive stress, WERR, RI, shrinkage, or any combination thereof, which are described in more detail below) for the silicon-and-oxygen-containing material. The overall times for each deposition cycle 205 (encompassing all operations therein) may be about 10 seconds or less, about 9 seconds or less, about 8 seconds or less, about 7 seconds or less, about 6 seconds or less, about 5 seconds or less, about 4 seconds or less, about 3 second or less, about 2.5 second or less, about 2 seconds or less, about 1.5 second or less, about 1 second or less, about 0.5 seconds or less, about 0.5 seconds to about 10 seconds, about 0.5 seconds to about 5 seconds, about 0.5 seconds to about 2.5 second, about 0.5 seconds to about 1.5 seconds, about 1 second to about 5 seconds, about 3 seconds to about 7 seconds, or about 5 seconds to about 10 seconds.

The conditions of each operation with the deposition cycle 205 may be the same for each iteration or may change for different iterations.

The deposition cycle 205 is iteratively repeated x number of times. x may be about 3 or more, about 5 or more, about 10 or more, about 20 or more, about 30 or more, about 40 or more, about 50 or more, about 100 or less, about 90 or less, about 80 or less, about 70 or less, about 60 or less, about 50 or less, about 40 or less, about 3 to about 100, about 3 to about 50, about 5 to about 50, about 10 to about 50, about 20 to about 60, about 30 to about 70, about 40 to about 80, or about 50 to about 100 or more.

After the iteratively repeated 210 deposition cycles 205, the method 200 includes the densification operation 215. Optionally, one or more additional operations may be between the iteratively repeated 210 deposition cycles 205 and the densification operation 215. For example, an additional operation 225 followed by an additional operation 230 may be performed before the densification operation 215. The densification operation 215 would convert the silicon-containing material deposited in the additional operation 225 to a densified silicon-and-oxygen-containing material.

The illustrated densification operation 215 includes one operation 245. The operation 245 exposes the silicon-and-oxygen containing material to an oxygen plasma to convert the silicon-and-oxygen containing material to a densified silicon-and-oxygen-containing material where the densified silicon-and-oxygen containing material has a higher quality, as described above, greater than the silicon-and-oxygen containing material. The plasma may be formed from an oxygen-containing precursor. Oxygen-containing precursors that may be used in method 200 may be or include any number of oxygen-containing precursors. For example, the oxygen-containing precursor may be or include nitrous oxide (N₂O), water (H₂O), diatomic oxygen (O₂), ozone (O₃), a combination of one or more of these, or any other oxygen-containing materials. Inert gas like argon may also be present.

The increase in quality of the resultant densified silicon-and-oxygen-containing material depends on, among other things, the plasma power and the exposure time. Generally, increased plasma power and increased exposure time improve the quality of a silicon-and-oxygen-containing material. However, each of the plasma power and exposure time reach a self-limiting saturation. Therefore, the plasma power and exposure time should be preferably chosen to minimize time while achieving the desired properties (e.g., higher quality, which can be characterized by compressive stress, WERR, RI, shrinkage, or any combination thereof, which are described in more detail below) for the densified silicon-and-oxygen-containing material.

Generally, the plasma power in operation 245 may be greater than the plasma power in operation 235, and/or the exposure time in operation 245 may be greater than the exposure time in operation 235. In a nonlimiting example, the plasma power in operation 245 may be about 1500 W to about 2500 W, and the plasma power in operation 235 may be about 1 W to about 2000 W provided the plasma power in operation 235 is lower than the plasma power in operation 245. In another nonlimiting example, the exposure time in operation 245 may be about 1 second to about 30 seconds, and the exposure time in operation 235 may be about 0.1 seconds to about 1 second provided the exposure time in operation 235 is lower than the exposure time in operation 245. In yet another nonlimiting example, the plasma power in operation 245 may be about 1500 W to about 2500 W with an exposure time of about 1 second to about 30 seconds, and the plasma power in operation 235 may be about 1 W to about 2000 W for about 0.1 seconds to about 1 second exposure time, provided (a) the plasma power in operation 235 is lower than the plasma power in operation 245 and/or (b) the exposure time in operation 235 is lower than the exposure time in operation 245.

The plasma power in operation 245 may be about 500 W or greater, about 1000 W or greater, about 1250 W or greater, about 1500 W or greater, about 500 W to about 2500 W, about 500 W to about 1500 W, about 1000 W to about 2500 W, about 1000 W to about 2000 W, or about 1500 W to about 2500 W or greater.

The exposure time (or length of time of operation 245 is performed) may be about 1 second or greater, about 1.5 seconds or greater, about 2 second or greater, about 2.5 seconds or greater, about 5 second or greater, about 10 seconds or greater, about 1 second to about 60 seconds, about 1 second to about 40 seconds, about 1 second to about 30 seconds, about 3 seconds to about 25 seconds, about 5 seconds to about 45 seconds, or about 10 seconds to about 60 seconds.

While forming the plasma of the oxygen-containing precursor in operation 245, a temperature within the semiconductor processing chamber may be maintained at greater than or about 450° C., and may be maintained at greater than or about 500° C., greater than or about 550° C., greater than or about 600° C., or more. The temperature may be maintained at less than or about 650° C. while forming the plasma of the oxygen-containing precursor, and may be maintained at less than or about 600° C., less than or about 550° C., less than or about 500° C., or less. In embodiments where the plasma of the oxygen-containing precursor is formed, the oxygen-containing precursor may include a one or both of N₂O and O₂.

After operation 245, the densification operation 215 may optionally include an operation (not illustrated) where the processing region is purged to remove excess oxygen plasma and/or byproducts from the treatment of the silicon-and-oxygen-containing material to produce the densified silicon-and-oxygen-containing material. Purging may be achieved by reducing the pressure in the semiconductor processing chamber or flowing a gas (e.g., an inert gas like argon or nitrogen) through the semiconductor processing chamber.

The conditions for each operation within the densification operation 215 may be chosen to achieve a densified silicon-and-oxygen-containing material with the properties described above. Preferably, the conditions other than time are selected to allow for each operation to be a minimal time while achieving the desired properties for the densified silicon-and-oxygen-containing material. The overall times for each densification operation 215 (encompassing all operations therein) may be about 120 seconds or less, about 90 seconds or less, about 60 seconds or less, about 50 seconds or less, about 40 seconds or less, about 30 seconds or less, about 1 second to about 120 seconds, about 1 second to about 90 seconds, about 5 seconds to about 120 seconds, about 5 seconds to about 90 seconds, about 10 seconds to about 120 seconds, or about 10 seconds to about 90 seconds.

The iteratively repeated 210 deposition cycle 205 and densification operation 215 are iteratively repeated 220 y number of times. y may be about 2 or more, about 3 or more, about 4 or more, about 5 or more, about 10 or more, about 15 or more, about 50 or less, about 40 or less, about 30 or less, about 20 or less, about 10 or less, about 2 to about 50, about 2 to about 30, about 3 to about 50, about 3 to about 30, about 3 to about 10, about 5 to about 25, about 10 to about 40, or about 15 to about 50 or more.

The conditions of each operation with the densification operation 215 may be the same for each iteration or may change for different iterations.

During each operation, the semiconductor processing chamber, the pedestal, or the substrate may be maintained at a variety of temperatures. In some embodiments the temperature of the semiconductor processing chamber, the pedestal, or the substrate may be maintained at less than or about 700° C., less than or about 650° C., less than or about 600° C., less than or about 550° C., less than or about 500° C., or less. In embodiments, the temperature of the semiconductor processing chamber, the pedestal, or the substrate may be maintained at greater than or about 300° C., greater than or about 350° C., greater than or about 400° C., greater than or about 450° C., greater than or about 500° C., or more, which may facilitate thermal decomposition of the precursors, allowing the plasma-free deposition to be performed. The pressure may be changed between two consecutive operations. In some instances, the temperature may be consistent (e.g., within a 50° C. range) throughout all operations.

During each operation, the semiconductor processing chamber may be maintained at a variety of pressures at which depositions may be performed. For example, a pressure within the semiconductor processing chamber may be maintained at greater than or about 100 Torr while depositing the silicon-containing materials, and may be maintained at greater than or about 150 Torr, greater than or about 200 Torr, greater than or about 250 Torr, greater than or about 300 Torr, greater than or about 350 Torr, greater than or about 400 Torr, or more. Similarly, the pressure within the semiconductor processing chamber may be maintained at less than or about 500 Torr while depositing the silicon-containing materials, and may be maintained at less than or about 450 Torr, less than or about 400 Torr, less than or about 350 Torr, less than or about 300 Torr, less than or about 250 Torr, less than or about 200 Torr, or less. The pressure may be changed between two consecutive operations. In some instances, the pressure may be consistent (e.g., within a 50 Torr range) throughout all operations.

The layer (e.g., layers 320a, 320b) comprising the silicon-and-oxygen-containing material after completion of the iteratively repeated 210 deposition cycle 205 and before the densification operation 215 may be characterized by a thickness of about 3 Å or more, about 5 Å or more, about 10 Å or more, about 3 Å to about 100 Å, about 3 Å to about 50 Å, about 3 Å to about 20 Å, about 5 Å to about 30 Å, about 10 Å to about 50 Å, or about 10 Å to about 100 Å. Without being limited by theory, it is believed that thicker layers of the silicon-and-oxygen-containing material may need higher plasma power and/or longer exposure times to effectively execute the densification operation 215.

Again, the quality of a silicon-and-oxygen-containing material may be characterized by the compressive stress (where higher compressive stress indicates higher quality), wet etch rate ratio (WERR) (in 1% HF) relative to thermal oxide (where lower WERR indicates higher quality), refractive index (RI) (where higher RI indicates higher quality), shrinkage (where less shrinkage indicates higher quality), or any combination thereof. As described above, the conditions (e.g., time, plasma power, and the like) of individual operations in the method effect the quality of the silicon-and-oxygen-containing material and the densified silicon-and-oxygen-containing material.

For the purposes of this application, a higher-stress material is characterized by an absolute value of stress, either positive or negative, that is greater than the absolute value of a lower-stress material. The convention used here is that positive stress is characterized as tensile stress, negative stress is characterized as compressive stress, and no stress (i.e., 0 GPa) is characterized as neutral stress. Positive (i.e., tensile) stress may characterized by an outward pushing force that may be created by the expansion of a material. Negative (i.e., compressive) stress may be characterized by an inward pulling force that may be created by the contraction of the material. The silicon-and-oxygen-containing material after the iteratively repeated deposition cycles may be characterized by a compressive stress of about −100 MPa or more, about −150 MPa or more, about −200 MPa or more, about −250 MPa or more, about −250 MPa to about −50 MPa, about −225 MPa to about −50 MPa, about −200 MPa to about −50 MPa, about −175 MPa to about −50 MPa, or about −150 MPa to about −50 MPa. The densified silicon-and-oxygen-containing material after the deposition cycle may be characterized by a compressive stress of about −200 MPa or less, about −225 MPa or less, about −250 MPa or less, about −275 MPa or less, about −300 MPa or less, about −350 MPa to about −200 MPa, about −325 MPa to about −200 MPa, about −300 MPa to about −200 MPa, about −275 MPa to about −200 MPa, or about −300 MPa to about −225 MPa. The improvement in compressive stress from the silicon-and-oxygen-containing material to the densified silicon-and-oxygen-containing material (calculated as the absolute value of the difference between the two compressive stresses that is then divided by the absolute value of compressive stress of the silicon-and-oxygen-containing material and reported as a percentage) may be about 10% or more, about 20% or more, about 30% or more, about 40% or more, about 50% or more, about 10% to about 200%, about 10% to about 100%, about 25% to about 100%, about 50% to about 150%, or about 75% to about 200% or more. The compressive stress can be measured by a method that includes using an ellipsometer to measure the bow of the waver before and after deposition. When the bow values are coupled with the thickness of the film, the stress can be calculated.

The silicon-and-oxygen-containing material after the iteratively repeated deposition cycles may be characterized by a WERR (in 1% HF) relative to thermal oxide of about 1.5 or more, about 2 or more, about 2.5 or more, about 1.5 to about 4, about 1.5 to about 3, about 2 to about 4, or about 2 to about 3. The densified silicon-and-oxygen-containing material after the deposition cycle may be characterized by a WERR (in 1% HF) relative to thermal oxide of about 2 or less, about 1.5 or less, about 1 or less, about 0.1 to about 2, about 0.1 to about 1.5, about 0.1 to about 1, or about 0.5 to about 1.5. The improvement in WERR from the silicon-and-oxygen-containing material to the densified silicon-and-oxygen-containing material (calculated as the absolute value of the difference between the two WERRs that is then divided by the WERR of the silicon-and-oxygen-containing material and reported as a percentage) may be about 10% or more, about 20% or more, about 30% or more, about 40% or more, about 50% or more, about 10% to about 200%, about 10% to about 100%, about 25% to about 100%, about 50% to about 150%, or about 75% to about 200% or more. A WERR may be defined as the relative etch rate (e.g., Å/min) of the silicon-and-oxygen-containing material in a 1% HF compared to the etch rate in 1% HF of a thermally-grown silicon oxide layer formed on the same substrate. A WERR of 1.0 means the silicon-and-oxygen-containing material in question has the same etch rate as a thermal oxide layer, while a WERR of greater than 1 means the silicon-and-oxygen-containing material etches at a faster rate than thermal oxide.

RI of a silicon-and-oxygen-containing material (densified or otherwise) correlates to the amount of oxidation in the silicon-and-oxygen-containing material, where higher RI indicates higher quality silicon-and-oxygen-containing material. The silicon-and-oxygen-containing material after the iteratively repeated deposition cycles may be characterized by a RI of about 1.5 or less, about 1.4 or less, about 1.3 or less, about 1 to about 1.5, about 1 to about 1.4, about 1 to about 1.3, or about 1 to about 1.2. The densified silicon-and-oxygen-containing material after the deposition cycle may be characterized by a RI of about 1.1 or more, about 1.3 or more, about 1.5 or more, about 1.1 to about 2, about 1.3 to about 2, or about 1.5 to about 2. The improvement in RI from the silicon-and-oxygen-containing material to the densified silicon-and-oxygen-containing material (calculated as the absolute value of the difference between the two RIs that is then divided by the RI of the silicon-and-oxygen-containing material and reported as a percentage) may be about 10% or more, about 20% or more, about 30% or more, about 40% or more, about 50% or more, about 10% to about 100%, about 25% to about 100%, or about 50% to about 100% or more. Refractive index may be measured using an ellipsometer.

Shrinkage of a silicon-and-oxygen-containing material (densified or otherwise) measures the change in thickness of the silicon-and-oxygen-containing material after annealing, where less shrinkage indicates a higher quality silicon-and-oxygen-containing material. The silicon-and-oxygen-containing material after the iteratively repeated deposition cycles may be characterized by a shrinkage of about 0.3% or less, about 0.2% or less, about 0.1% or less, about 0.01% to about 0.3%, about 0.01% to about 0.2%, or about 0.01% to about 0.1%. The densified silicon-and-oxygen-containing material after the deposition cycle may be characterized by a shrinkage of about 0.1% or less, about 0.08% or less, about 0.06% or less, about 0.001% to about 0.1%, about 0.001% to about 0.08%, or about 0.001% to about 0.06%. The improvement in shrinkage from the silicon-and-oxygen-containing material to the densified silicon-and-oxygen-containing material (calculated as the absolute value of the difference between the two shrinkages that is then divided by the shrinkage of the silicon-and-oxygen-containing material and reported as a percentage) may be about 10% or more, about 20% or more, about 30% or more, about 40% or more, about 50% or more, about 10% to about 100%, about 25% to about 100%, or about 50% to about 100% or more. Shrinkage may be determined by comparing the thickness of a silicon-and-oxygen-containing material before and after annealing at 800° C. for 1 hour in 100% nitrogen.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such precursors, and reference to “the silicon-containing material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
i) iteratively repeating a deposition cycle x times on a substrate disposed within a processing region of a semiconductor processing chamber, wherein 3≤x≤100, and wherein the deposition cycle comprises:
i-a) depositing a silicon-containing material on the substrate;
i-b) purging the processing region after operation i-a;
i-c) exposing the silicon-containing material to a first oxygen plasma to convert the silicon-containing material to a silicon-and-oxygen-containing material, wherein the first oxygen plasma is generated at a first plasma power, and wherein the exposing is for a first time;
i-d) purging the processing region after operation i-c;
ii) optionally repeating operations i-a and i-b;
iii) performing a densification operation by exposing the silicon-and-oxygen-containing material to a second oxygen plasma to produce a densified silicon-and-oxygen-containing material, wherein the second oxygen plasma is generated at a second plasma power, wherein the exposing is for a second time, and wherein the first plasma power is lower than the second plasma power and/or the first time is shorter than the second time; and
iv) iteratively performing operations i through iii y times, wherein 2≤y≤50.

2. The semiconductor processing method of claim 1, wherein 5≤x≤50.

3. The semiconductor processing method of claim 1, wherein 3≤y≤10.

4. The semiconductor processing method of claim 1, wherein the deposition cycle is 3 seconds or less.

5. The semiconductor processing method of claim 1, wherein the first plasma power is about 100 W to about 2500 W, and wherein the second plasma power is about 1500 W to about 2500 W.

6. The semiconductor processing method of claim 1, wherein the first time is about 0.1 seconds to about 1 second, and wherein the second time is about 1 second to about 30 seconds.

7. The semiconductor processing method of claim 1, wherein the substrate defines one or more features along the substrate, and wherein the silicon-and-oxygen-containing material extends within the one or more features along the substrate.

8. The semiconductor processing method of claim 1, wherein a pressure within the processing region is maintained at greater than or about 100 Torr while depositing the silicon-containing material on the substrate.

9. The semiconductor processing method of claim 1, wherein the silicon-containing material is or is derived from a silicon-containing precursor that comprises one or more of: silane (SiH₄), dislane (Si₂H₆), silicon tetrachloride (SiCl₄), tetraethyl orthosilicate (TEOS), and aminosilane.

10. The semiconductor processing method of claim 1, wherein the silicon-and-oxygen-containing material after operation i has a thickness of about 3 Å to about 100 Å.

11. The semiconductor processing method of claim 1, wherein the silicon-and-oxygen-containing material has a compressive stress of about −225 MPa to about −50 MPa, and the densified silicon-and-oxygen-containing material has a compressive stress of about −350 MPa to about −200 MPa, and wherein the compressive stress of the silicon-and-oxygen-containing material is greater than the compressive stress of the densified silicon-and-oxygen-containing material.

12. The semiconductor processing method of claim 1, wherein the silicon-and-oxygen-containing material has a wet etch rate ratio (WERR) (in 1% HF) relative to thermal oxide of about 1.5 to about 4, and the densified silicon-and-oxygen-containing material has a WERR (in 1% HF) relative to thermal oxide of about 0.1 to about 2, and wherein the WERR of the silicon-and-oxygen-containing material is greater than the WERR of the densified silicon-and-oxygen-containing material.

13. The semiconductor processing method of claim 1, wherein the silicon-and-oxygen-containing material has a refractive index of about 1 to about 1.5, and the densified silicon-and-oxygen-containing material has a refractive index of about 1.1 to about 2, and wherein the refractive index of the silicon-and-oxygen-containing material is less than the refractive index of the densified silicon-and-oxygen-containing material.

14. A semiconductor processing method comprising:
i) iteratively repeating a deposition cycle x times on a substrate in a processing region of a semiconductor processing chamber, wherein 3≤x≤100, wherein the deposition cycle comprises:
i-a) depositing a silicon-containing material on the substrate;
i-b) purging the processing region after operation i-a;
i-c) exposing the silicon-containing material to a first oxygen plasma to convert the silicon-containing material to a silicon-and-oxygen-containing material, wherein the first oxygen plasma is generated at a first plasma power, wherein the exposing is for a first time, and wherein in each iteration of the deposition cycle the first plasma power is about 100 W to about 2500 W and the first time is about 0.2 seconds to 3 seconds, each independently chosen for each iteration of the deposition cycle;
i-d) purging the processing region after operation i-c;
ii) optionally repeating operations i-a and i-b;
iii) performing a densification operation by exposing the silicon-and-oxygen-containing material to a second oxygen plasma to produce a densified silicon-and-oxygen-containing material, wherein the second oxygen plasma is generated at a second plasma power, wherein the exposing is for a second time, wherein the first plasma power is lower than the second plasma power and/or the first time is shorter than the second time, and wherein in each iteration of the densification operation the second plasma power is about 1000 W to about 2500 W and the second time is about 1 second to 40 seconds, each independently chosen for each iteration of the densification operation; and
iv) iteratively performing operations i through iii y times while the substrate is maintained in the processing region, wherein 2≤y≤50.

15. The semiconductor processing method of claim 14, wherein 5≤x≤50.

16. The semiconductor processing method of claim 14, wherein 3≤y≤20.

17. The semiconductor processing method of claim 14, wherein the deposition cycle is 1.5 seconds or less.

18. The semiconductor processing method of claim 14, wherein the first plasma power is about 500 W to about 2500 W, and wherein the second plasma power is about 1500 W to about 2500 W.

19. The semiconductor processing method of claim 14, wherein the first time is about 0.1 seconds to about 0.7 seconds, and wherein the second time is about 3 seconds to about 25 seconds.

20. A semiconductor processing method comprising:
i) iteratively repeating a deposition cycle x times on a substrate in a processing region of a semiconductor processing chamber, wherein 3≤x≤100, wherein the deposition cycle comprises:
i-a) depositing a silicon-containing material on the substrate;
i-b) purging the semiconductor processing chamber after operation i-a;
i-c) exposing the silicon-containing material to a first oxygen plasma to convert the silicon-containing material to a silicon-and-oxygen-containing material, wherein the first oxygen plasma is generated at a first plasma power, wherein the exposing is for a first time, and wherein in each iteration of the deposition cycle the first plasma power and the first time can vary;
i-d) purging the semiconductor processing chamber after operation i-c;
ii) optionally repeating operations i-a and i-b;
iii) performing a densification operation by exposing the silicon-and-oxygen-containing material to a second oxygen plasma to produce a densified silicon-and-oxygen-containing material, wherein the second oxygen plasma is generated at a second plasma power, wherein the exposing is for a second time, wherein in each iteration of the densification operation the second plasma power and the second time can vary, and wherein the first plasma power is lower than the second plasma power and/or the first time is shorter than the second time; and
iv) iteratively performing operations i through iii y times while the substrate is maintained in the processing region of the semiconductor processing chamber, wherein 2≤y≤50, wherein each iteration of the operations i through iii produces a layer of the densified silicon-and-oxygen-containing material having a thickness of about 3 Å to about 100 Å.
